(19) United States
(12) Patent Application Publication
(10) Pub. No.: US 2009/0190648 A1
(43) Pub. Date: Jul. 30, 2009

(54) DIFFERENTIAL TRANSMITTER

(75) Inventors: Yoshihisa Sakano, Ukyo-Ku (JP); Keisuke Satou, Ukyo-Ku (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/355,867

(22) Filed: Jan. 19, 2009

(30) Foreign Application Priority Data
Jan. 18, 2008 (JP) JP2008-009128
Jan. 18, 2008 (JP) JP2008-009140

(51) Int. Cl. H03K 5/159; H04L 27/00

(52) U.S. Cl. 375/232; 375/299

(57) ABSTRACT

A TMDS driver outputs differential signals via a pair of differential signal lines. The input differential pair includes a first transistor and a second transistor with one terminals thereof connected to each other so as to form a common terminal, and operates with termination resistors, which are arranged on the side of a differential receiver connected via the differential signal lines, as a part of the load. A tail current source supplies constant current to the input differential pair. An impedance adjusting unit is provided between the input differential pair and the differential signal lines, and adjusts the load impedance of the first transistor and the second transistor.

### BACKGROUND OF THE INVENTION

1. Field of the Invention

The present invention relates to a differential transmitter which transmits differential signals, and an equalizer which performs waveform-shaping of differential signals.

2. Description of the Related Art

In recent years, the HDMI (High-Definition Multimedia Interface) standard which allows video signals and audio signals to be transmitted/received at high speeds among digital appliances such as TV sets, DVD (Digital Versatile Disc) players, and AV amplifiers, has begun to come into commonplace use.

The HDMI standard allows video signals, audio signals, and control signals to be transmitted via a signal cable using differential signals. The HDMI standard has a problem in that, in a case in which there is a great distance between the devices connected according to the HDMI standard, the quality of the waveform of the differential signal deteriorates due to the long cable therebetween, leading to an increased error rate.

In order to restore the differential signal having deteriorated quality due to signal transmission, an equalizer which enhances or attenuates a particular frequency component of the differential signals is provided. The HDMI standard provides data transmission at a high data bit rate using the differential signals. This requires high-speed responsivity of the equalizer.

### [Patent Document 1]

Japanese Patent Application Laid Open No. 2003-204291

### [Patent Document 2]

PCT Japanese Translation Patent Publication No. 2005-511214

### SUMMARY OF THE INVENTION

In conventional arrangements, an equalizer which performs waveform-shaping of high-speed differential signals and a peripheral analog circuit thereof are formed using bipolar transistors having excellent high-speed operation. An integrated digital circuit formed using such analog circuits and CMOSs requires a BiCOMS process, leading to a problem of costs, and limitations on the degree-of-freedom of the design.

The present invention has been made in view of such a situation. Accordingly, it is a general purpose of an embodiment to provide a differential transmitter with a reduced error rate. Furthermore, it is another general purpose of an embodiment to provide an equalizer formed using a CMOS process.

1. An embodiment of the present invention relates to a differential transmitter which outputs differential signals via a pair of differential signal lines. The differential transmitter includes: an input differential pair which includes first and second transistors with one terminals connected to each other so as to form a common terminal, and operates with termination resistors on a receiver side as a load; a tail current source which supplies constant current to the input differential pair; an impedance adjusting unit which is provided between the input differential pair and the differential signal lines, and adjusts the load impedance on the first and second transistors.

With such an embodiment, by reducing the load impedance on the input differential pair while reducing the amplitude on the receiver side according to the trade-off relation, the rising time and the falling time (which will also be referred to as “transition time” hereafter) can be reduced, thereby reducing the error rate.

Also, the impedance adjusting unit may include a variable impedance element provided between the other terminal of the first transistor and the other terminal of the second transistor.

The variable impedance element may be configured so as to allow the state to be switched between a first state in which the impedance thereof is substantially infinite and a second state in which the impedance thereof is four to nine times the terminal resistance. For example, in a case in which the terminal resistance is 50Ω, the resistance of the variable impedance element in the second state is set to 200 to 450Ω, and is preferably set to 300 to 400Ω.

Also, the impedance adjusting unit may include a first switch provided between the other terminal of the first transistor and the other terminal of the second transistor.

Also, the impedance adjusting unit may further include a first resistor provided in series with the first switch between the other terminal of the first transistor and the other terminal of the second transistor.

Also, the impedance adjusting unit may further include a second resistor provided opposite to the first resistor across the first switch between the other terminal of the first transistor and the other terminal of the second transistor.

Also, the impedance adjusting unit may include: a first variable impedance element provided between the other terminal of the first transistor and a power supply terminal; and a second variable impedance element provided between the other terminal of the second transistor and the power supply terminal.

Also, the impedance adjusting unit may include: a second switch provided between the other terminal of the first transistor and a power supply terminal; and a third switch provided between the other terminal of the second transistor and the power supply terminal.

Also, the impedance adjusting unit may further include: a fourth resistor provided in series with the second switch between the other terminal of the first transistor and the power supply terminal; and a fifth resistor provided in series with the third switch between the other terminal of the second transistor and the power supply terminal.

The differential transmitter may be monolithically integrated on a single semiconductor substrate. Examples of “arrangements monolithically integrated” include: an arrangement in which all the elements of a circuit are formed on a single semiconductor substrate; and an arrangement in which principal elements of a circuit are monolithically integrated. Also, a part of the resistors, capacitors, and so forth, for adjusting circuit constants, may be provided in the form of external elements as to the semiconductor substrate. The differential transmitter circuit is integrated in the form of a single LSI, thereby providing a reduced circuit area.

Another embodiment of the present invention relates to an electronic apparatus. The electronic apparatus includes a differential transmitter according to any one of the above-described embodiments.

2. An equalizer according to an embodiment of the present invention is an equalizer which performs waveform-shaping of input differential signals. The equalizer includes multiple differential amplifiers connected in a multi-stage manner. With such an embodiment, each differential amplifier has a configuration including an input differential pair configured of two MOSFETs (Metal Oxide Semiconductor Field Effect Transistor). Furthermore, the gain frequency properties of the stages are set independently of one another.

With such an embodiment, all the stages are configured of differential amplifiers having different gain frequency properties. This provides the frequency properties as a whole close to desired frequency properties.

Also, the gain of the final-stage differential amplifier may be set to a lowest value.

There is a trade-off relation between the gain of the amplifier and the frequency band. This leads to great parasitic capacitance that occurs on the output side of the final-stage amplifier, thereby leading to a difficulty in providing the gain over the wide frequency band. Accordingly, by widening the frequency band while setting the gain of the final-stage differential amplifier to a small value, such an arrangement ensures the frequency band necessary for the equalizer as a whole.

Also, the differential amplifier may include: an input differential pair configured of two MOSFETs (Metal Oxide Semiconductor Field Effect Transistor); resistive loads connected to the drain sides of the two MOSFETs; a tail current source connected to the source sides of the two MOSFETs; and an impedance circuit provided between the sources of the two MOSFETs. Also, the drain-side voltages of the two MOSFETs may be output to the next stage.

Also, the impedance circuit may include a first resistor and a first capacitor provided in parallel between the sources of the two MOSFETs. Also, there may be a difference in the resistance of the first resistor and the capacitance of the first capacitor among the stages of the differential amplifiers.

Also, the number of the stages of the differential amplifiers may be three. The more the number of the stages of the amplifiers is, the greater the degree-of-freedom of adjustment of gain is, but the delay time of the equalizer is also increased. With the above-described arrangement, three stages of the differential amplifiers are provided, thereby allowing the gain frequency properties to be optimized while maintaining the delay time in a suitable range.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of a differential transmitter according to a first embodiment;

FIG. 2 is a circuit diagram which shows an example configuration of a TMDS driver shown in FIG. 1;

FIG. 3 is a circuit diagram which shows another example configuration of the TMDS driver shown in FIG. 1;

FIG. 4 is a waveform diagram which shows differential signals output from the differential transmitter shown in FIG. 1 through FIG. 3;

FIG. 5 is a block diagram which shows an HDMI selector using equalizers according to a second embodiment;

FIGS. 6A and 6B are circuit diagrams which show a configuration of the equalizer according to the second embodiment; and

FIG. 7 is a diagram which shows the frequency properties with respect to the gain of the differential amplifier of each stage.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A is connected to the member B” includes a state in which the member A is indirectly connected to the member B via another member that does not affect the electric connection therebetween, in addition to a state in which the member A is physically and directly connected to the member B. In the same way, the state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

### First Embodiment

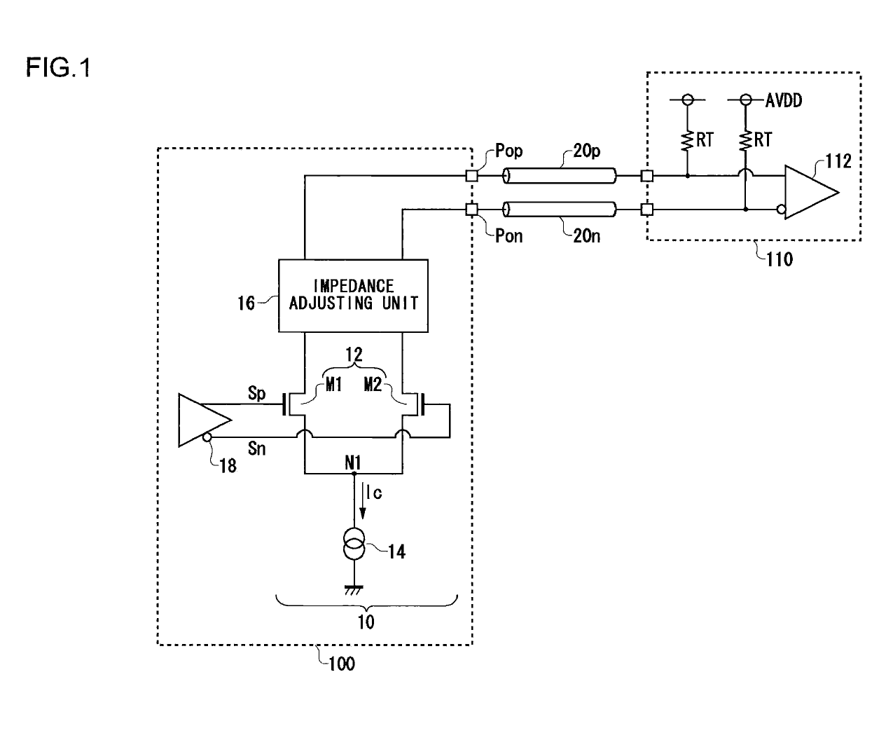

FIG. 1 is a circuit diagram which shows a configuration of a differential transmitter 100 according to a first embodiment. FIG. 1 shows differential signal lines 20 and a differential receiver 110, in addition to the differential transmitter 100. The differential transmitter 100 and the differential receiver 110 are connected via the differential signal lines 20. The differential receiver 110 includes termination resistors RT and a TMDS receiver 112 which receives differential signals transmitted via the differential signal lines 20.

The differential transmitter 100 includes a TMDS (Transition Minimized Differential Signaling) driver 10 and a differential signal generating unit 18. The differential transmitter 100 is monolithically integrated on a single semiconductor substrate. The differential signal generating unit 18 generates differential signals Sp and Sn to be transmitted, and outputs the differential signals thus generated to the TMDS driver 10. Alternatively, the differential signal generating unit 18 may receive the differential signals Sp and Sn input from an external circuit, and may output the differential signals thus received to the TMDS driver 10.

The TMDS driver 10 according to the embodiment has a de-emphasis function for adjusting the amplitude of the differential signals to be output. The TMDS driver 10 includes an input differential pair 12, a tail current source 14, and an impedance adjusting unit 16, and transmits differential signals Sp′ and Sn′ via the differential signal lines connected to output terminals Pop and Pon.

The input differential pair 12 includes a first transistor M1 and a second transistor M2. The first transistor M1 and the second transistor M2 are N-channel MOSFETs (Metal Oxide Semiconductor Field Effect Transistor), and have one terminals (sources) connected to each other so as to form a common terminal. The other terminals (drains) of the first transistor M1 and the second transistor M2 are connected via the impedance adjusting unit 16 to differential signal lines 20p and 20n, respectively, as described later. The differential signals Sp and Sn to be transmitted are input to the control terminals (gates) of the first transistor M1 and the second transistor M2, respectively. The input differential pair 12 operates with the termination resistors RT on the differential receiver 110 side, which is connected via the differential signal lines 20, as a part of the load.

The tail current source 14 is connected to a common connection node N1 which connects the first transistor M1 and the second transistor M2, and supplies a constant current Ic to the input differential pair 12.

The impedance adjusting unit 16 is provided between the input differential pair 12 and the differential signal lines 20, and adjusts the load impedance on the first transistor M1 and the second transistor M2. The load impedance of the first transistor M1 and the second transistor M2 represents the impedance seen by the drains of the first transistor M1 and the second transistor M2 to the differential receiver 110 side via the differential signal lines 20.

The impedance adjusting unit 16 is configured so as to allow the load impedance for the input differential pair 12 to be switched between at least two states. The impedance adjusting unit 16 is preferably configured so as to allow the state to be switched between a first state (normal driving state) in which the load impedance on the input differential pair 12 matches the termination resistors RT and a second state (de-emphasis state) in which the load impedance on the input differential pair 12 is smaller than that of the termination resistors RT. In addition, a third state may be provided in which the load impedance on the input differential pair 12 is greater than that of the termination resistor RT.

In general, the impedance adjusting unit 16 is set to the first state in which the TMDS driver 10 of the differential transmitter 100 operates with the termination resistors RT on the differential receiver 110 side, i.e., 50Ω as the load.

When the impedance adjusting unit 16 is set to the second state, the load impedance on the input differential pair 12 is reduced. The load impedance (resistance component) on the input differential pair 12 and the capacitance of the differential signal lines 20 form a low-pass filter. Accordingly, the cutoff frequency is raised according to reduction in the load impedance. As a result, the rising time and the falling time (which will also be referred to as “transition time” hereafter) of the differential signals Sp′ and Sn′ can be reduced by reducing the amplitude on the receiver side, using the trade-off relation therebetween. This increases the aperture ratio of the eye pattern of the differential signals Sp′ and Sn′ in the time-axis direction, thereby reducing the error rate.

In a case in which RT is 50Ω, the load impedance RT′ on the input differential pair 12 in the second state is preferably set to around 40 to 45Ω.

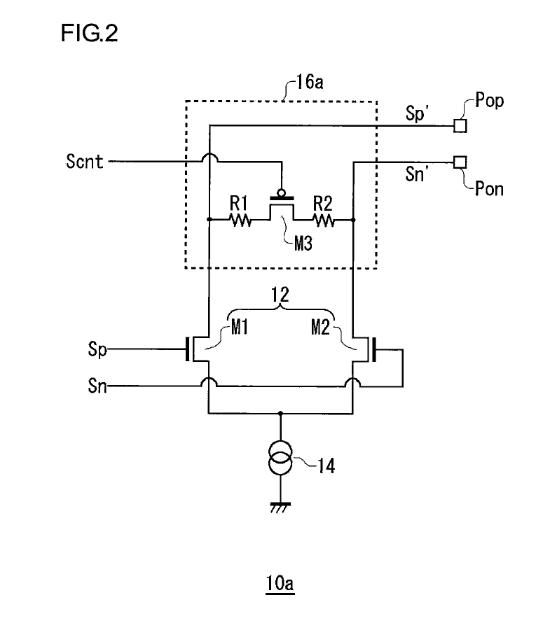

FIG. 2 is a circuit diagram which shows an example configuration of the TMDS driver shown in FIG. 1. In a TMDS driver 10a shown in FIG. 2, an impedance adjusting unit 16a includes a variable impedance element provided between the other terminal (drain) of the first transistor M1 and the other terminal (drain) of the second transistor M2.

The variable impedance element is switched between a first state which is substantially the open state and a second state which provides an effective impedance.

The impedance adjusting unit 16a includes a first switch M3, a first resistor R1, and a second resistor R2. The first switch M3 is provided between the other terminal (drain) of the first transistor M1 and the other terminal (drain) of the second transistor M2. The first switch M3 comprises a P-channel MOSFET, and the ON/OFF operation thereof is controlled according to a control signal Scnt input to the gate. The control signal Scnt is input from a circuit external to the differential transmitter 100. The first resistor R1 is provided in series with the first switch M3 between the other terminal (drain) of the first transistor M1 and the other terminal (drain) of the second transistor M2. The second resistor R2 is provided opposite to the first resistor R1 across the first switch M3 between the other terminal (drain) of the first transistor M1 and the other terminal (drain) of the second transistor M2.

When the first switch M3 is switched to the OFF state, the impedance adjusting unit 16a is switched to the first state. In this state, the input differential pair 12 transmits the differential signals Sp′ and Sn′ with the termination resistors RT as the load.

When the first switch M3 is switched to the ON state, the load impedance is reduced for each of the first transistor M1 and the second transistor M2. As a result, the transition time of the differential signals Sp′ and Sn′ can be reduced, thereby reducing the error rate.

With the resultant impedance of the first resistor R1, the second resistor R2, and the ON-resistance Ron3 of the first switch M3 as Radj, in the second state, the following Expression is satisfied: Radj=R1+R2+Ron3. In the first state, Radj is substantially infinite.

The load impedance RT′ on the input differential pair 12 in the second state is represented by the following Expression: RT′=RT×Radj/(RT+Radj), using the terminal resistance RT and the impedance Radj of the impedance adjusting unit 16a.

The impedance Radj is represented by the following Expression: Radj=(RT′×RT)/(RT−RT′). Accordingly, in a case in which the load impedance RT′ in the second state is to be set to a range between 40 and 45Ω, the impedance Radj should be set to a range between 200 and 450Ω. The impedance Radj is preferably set to a range between 300 and 400Ω.

Now, discussion will be made regarding the output impedance Rout of the TMDS driver 10. The output impedance Rout of the TMDS driver 10 in the first state is represented by the following Expression: Rout=1/(RT⁻¹+gm). When RT is 50Ω, and gm is 20 mS, Rout is 25Ω.

The output impedance Rout′ in the second state is represented by the following Expressions.

Rout′=1/(RT′⁻¹+gm′)

gm′=gm·√((RT+Radj)/Radj)

When RT is 50Ω, RT′ is 40 to 45Ω, and gm is 20 mS, Rout′ is 21 to 23Ω.

An arrangement may be made in which either the first resistor R1 or the second resistor R2 is eliminated. Such an arrangement provides a simple circuit configuration. It should be noted that, in a case in which the first resistor R1 and the second resistor R2 are provided to both terminals of the first switch M3, the first switch M3 is not directly connected to the output terminals Top and Ton. Thus, such an arrangement provides an improved function of protecting the circuit from electrostatic breakdown etc.

Also, an arrangement may be made in which the ON-resistance Ron3 of the first switch M3 is set to the aforementioned range, and both of the first resistor R1 and the second resistor R2 are eliminated. In this case, such an arrangement provides a simpler circuit configuration.

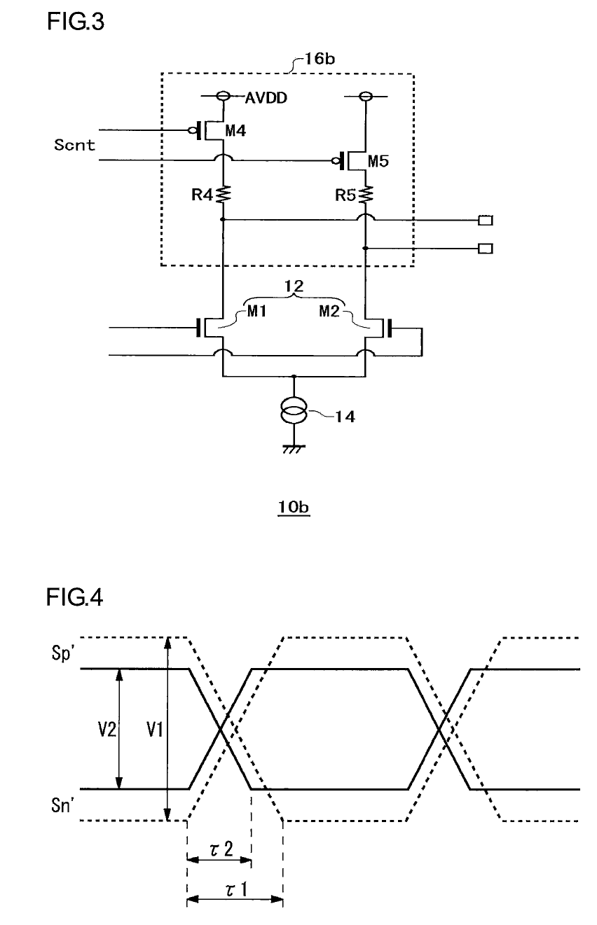

FIG. 3 is a circuit diagram which shows another example configuration of the TMDS driver shown in FIG. 1. An impedance adjusting unit 16b shown in FIG. 3 includes a first switch M3, a second switch M4, a fourth resistor R4, and a fifth resistor R5.

The second switch M4 is provided between the other terminal (drain) of the first transistor M1 and the power supply terminal AVDD. The third switch M5 is provided between the other terminal (drain) of the second transistor M2 and the power supply terminal AVDD. Each of the second switch M4 and the third switch M5 is a P-channel MOSFET, and the ON/OFF operation thereof is controlled according to a control signal Scnt.

The fourth resistor R4 is arranged in series with the second switch M4 between the other terminal (drain) of the first transistor M1 and the power supply terminal AVDD. The fifth resistor R5 is arranged in series with the third switch M5 between the other terminal (drain) of the second transistor M2 and the power supply terminal AVDD.

Seen from another perspective, the first switch M3 and the fourth resistor R4 form a first variable impedance element. The second switch M4 and the fifth resistor R5 form a second variable impedance.

With the TMDS driver 10b shown in FIG. 3, when the second switch M4 and the third switch M5 are switched to the OFF state, the load impedance on the input differential pair 12 is switched to the terminal resistance RT, thereby switching the state to the first state. On the other hand, when the second switch M4 and the third switch M5 are switched to the ON state, the load impedance is reduced for the first transistor M1 and the second transistor M2, thereby allowing the electric potentials at the signal lines to be switched at a high speed.

FIG. 4 is a waveform diagram which shows the differential signals Sp′ and Sn′ output from the differential transmitter 100 shown in FIG. 1 through FIG. 3. The broken lines indicate the waveforms in the first state, and the solid lines indicate the waveforms in the second state. In the first state indicated by the broken lines, the differential signals Sp′ and Sn′ have an amplitude of V1 and transition time of τ1. In the second state indicated by the solid lines, the differential signals Sp′ and Sn′ have an amplitude of V2 and transition time of τ2. As can be clearly understood from FIG. 4, V1 is greater than V2, and τ1 is greater than τ2. That is to say, there is a trade-off relation between the amplitude and the transition time.

In order to reduce the error rate, in many cases, conventional TMDS drivers employ a method in which the driving capability is raised by changing the size of the input differential pair 12. For example, a method has been employed in which the amplitude is temporarily raised during the transition time by setting the driving capability to a greater value, thereby raising the aperture ratio of the eye pattern. On the other hand, with the differential transmitter 100 according to the present embodiment, the transition speed is raised by reducing the load impedance for the input differential pair 12 while the amplitude is reduced. That is to say, the error rate is improved using an approach that differs from that used in conventional arrangements.

### Second Embodiment

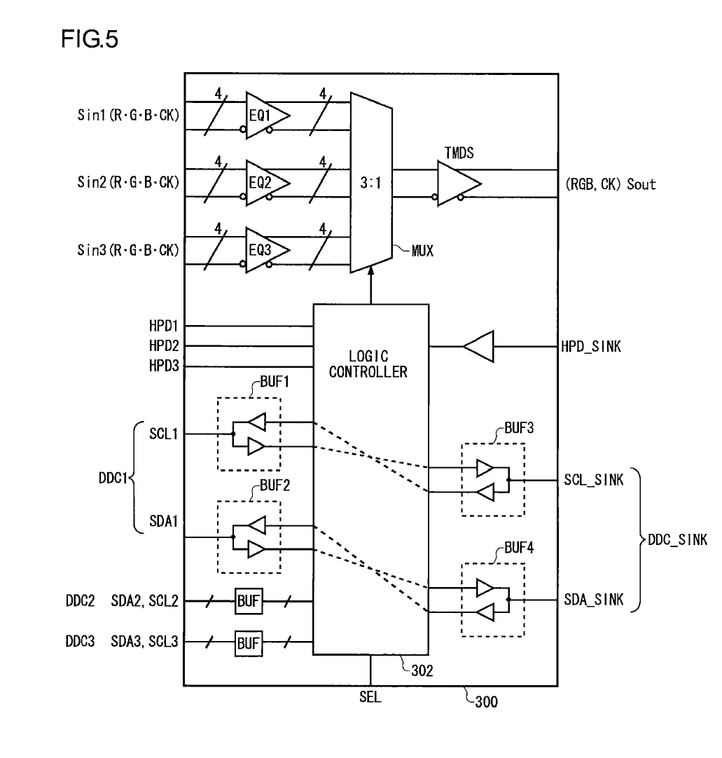

FIG. 5 is a block diagram which shows a configuration of an HDMI selector 300 employing an equalizer EQ according to a second embodiment. The HDMI selector 300 is connected to electronic apparatuses (or electronic circuits) stipulated by the HDMI standard, and switches the input/output paths. The HDMI selector 300 provides a function as a three-to-one multiplexer which transmits/receives video signals and audio signals stipulated by the HDMI standard between one selected from among three apparatuses connected on the input side and a single apparatus connected on the output side.

In the HDMI standard, a set of the video signal (S) line, the hot plug detection (HPD) line, and the display data channel (DDC) line form a single channel (cable). Accordingly, three channels (Sin1 through Sin3) are provided on the input side, and a single channel (Sout) is provided on the output side. The video signal S is supplied in the form of differential signals, including luminance signals R, G, and B in increments of colors, and a clock signal CK. Equalizers EQ1 through EQ3 are provided for the signals Sin1 through Sin3 on the input side, respectively. Each of the equalizers EQ1 through EQ3 enhances a particular frequency component, e.g., a high-frequency component in the differential signals, thereby providing a function as an input buffer which performs wave-shaping of a dulled waveform.

The three-to-one multiplexer MUX selects one from among the outputs of the equalizers EQ1 through EQ3, and outputs the output signal thus selected to the TMDS driver. The TMDS driver outputs, as an output signal Sout, the channel signal selected by the multiplexer MUX. In FIG. 5, each of the equalizers EQ1 through EQ3 and the TMDS driver is provided for a set of the luminance signals R, G, and B and the clock signal CK.

The logic controller 302 switches the connection destination for the multiplexer MUX according to an external selection signal SEL. Furthermore, the logic controller 302 receives hot plug detection signals HPD1 through HPD3 from the apparatuses on the input side and a hot plug detection signal HPD_SINK from the apparatus on the output side.

Each of the display data channel signals DDC1 through DDC3 includes information with respect to the input-side apparatus. The display data channel signal DDC_SINK includes the information with respect to the apparatus on the output side. The logic controller 302 connects the selected apparatus on the input side and the display channel of the apparatus on the output side. The input-side apparatus and the output-side apparatus communicate interactively via the display data channel. The display data channel employs an I²C bus. FIG. 5 shows a state in which the display data channel DDC1 is connected to the display data channel DDC_SINK.

Each of the display data channels DDC1 through DDC3 and DDC_SINK includes a clock signal SCL and a data signal SDA. Each display data channel includes a line buffer. For example, if we take note of the clock signal SCL, a buffer BUF1 of the input-side apparatus and a buffer BUF3 of the output-side apparatus form a pair which serves as a two-way buffer. On the other hand, if we take note of the data signal SDA, a buffer BUF2 of the input-side apparatus and a buffer BUF4 of the output-side apparatus form a pair which serves as a two-way buffer. Also, the display data channel DDC2 or DDC3 can be connected to DDC_SINK in the same way.

Detailed description will be made below regarding the equalizer EQ, which can be suitably applied to such an HDMI selector, according to the embodiment.

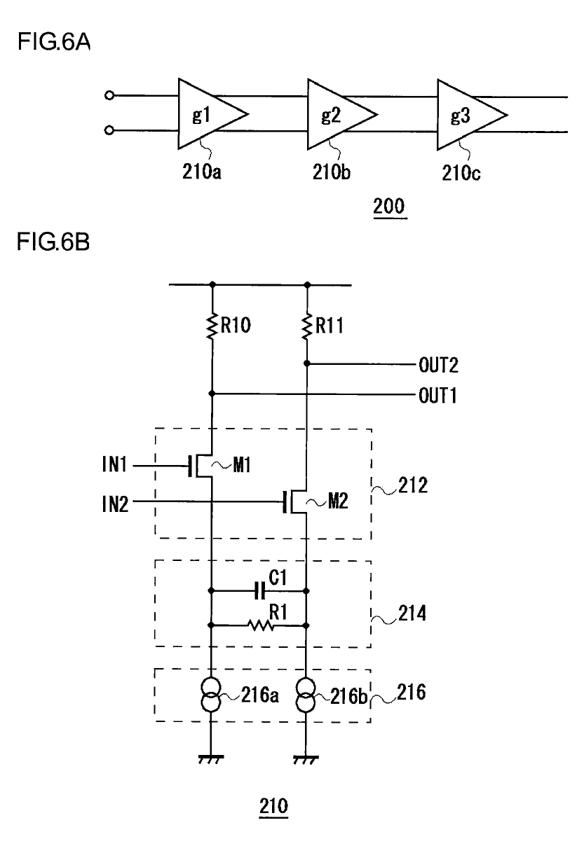

FIGS. 6A and 6B are circuit diagrams which show a configuration of an equalizer 200 according to the second embodiment. FIG. 6A shows the overall configuration of the equalizer 200. The point of difference between the equalizer 200 according to the embodiment and conventional arrangements is that the equalizer 200 according to the embodiment is formed using the CMOS process. By employing the CMOS process, such an arrangement has the following technical features.

The equalizer 200 includes multiple differential amplifiers 210a through 210c connected in a multi-stage manner. The differential amplifiers 210a through 210c have the same configuration and the gain frequency properties of these stages are configurable independently one another.

FIG. 6B is a circuit diagram which shows a configuration of the differential amplifier 210 for each stage. Each differential amplifier 210 amplifiers differential inputs IN1 and IN2, and generates differential outputs OUT1 and OUT2. The differential amplifier 210 has a configuration including an input differential pair 212 formed of two MOSFETs (Metal Oxide Semiconductor Field Effect Transistor). The two transistors included in the input differential pair will be referred to as the “transistors M1 and M2”.

The resistors R10 and R11, which form a resistor pair, are connected to the drain sides of the first and second transistors M1 and M2, respectively, and provide a function as a resistive load for the differential amplifier 210.

Tail current sources 216 are provided to the source sides of the two transistors M1 and M2. Specifically, the first current source 216a is connected to the source side of the first transistor M1, and the second current source 216b is connected to the source side of the second transistor M2. The input differential pair 212 is biased by the tail current sources 216.

An impedance circuit 214 is provided between the source of the first transistor M1 and the source of the second transistor M2. The impedance circuit 214 includes a first capacitor C1 and a first resistor R1. The first capacitor C1 and the first resistor R1 are provided in parallel between the source of the first transistor M1 and the source of the second transistor M2.

The differential amplifier 210 outputs the drain-side voltages OUT1 and OUT2 of the first transistor M1 and the second transistor M2 to the next stage.

The gain g of the differential amplifier 210 is represented by the ratio between the impedance Z1 on the drain side of the input differential pair 212 and the impedance Z2 on the source side thereof. The impedance Z2 on the source side is a resultant impedance of those of the impedance circuit 214 and the tail current sources 216. In general, the internal impedance of the current source can be assumed to be infinite, and accordingly, the impedance Z2 is substantially the same as that of the impedance circuit 214. Accordingly, the gain g of the differential amplifier 210 is defined by the resistances of the resistors R10 and R11, and the first resistor R1, and the capacitance of the first capacitor C1.

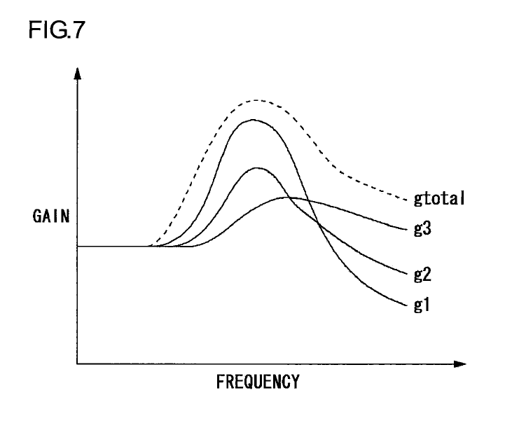

Next, description will be made regarding the gains of the differential amplifiers 210a through 210c provided in a three-stage manner. FIG. 7 is a diagram which shows the frequency properties with respect to the gains g1 through g3 of the differential amplifiers 210a through 210c. As shown in FIG. 7, different frequency properties are set for the gain g1 through g3 of the differential amplifiers 210a through 210c. The resistance of the first resistor R1, the capacitance of the first capacitor C1, and the resistances of the resistors R10 and R11 shown in FIG. 6B are set to different values for the differential amplifier 210 of each stage according to the required frequency properties.

As described above, the equalizer 200 is configured employing multiple differential amplifiers of the same type provided in a multi-stage manner, and different gain frequency properties are set for each stage. This allows the overall frequency properties thereof to be set close to the desired frequency properties.

As shown in FIG. 7, the gain g3 of the final-stage differential amplifier 210c is designed so as to have a smallest peak value, and so as to have a widest frequency band.

In general, there is a trade-off relation between the gain of the amplifier and the frequency band. With such an arrangement, great parasitic capacitance occurs on the output side of the final-stage differential amplifier 210c due to the wiring and the load of the next stage (multiplexer MUX shown in FIG. 5), leading to a difficulty in maintaining the gain over a wide frequency band. Accordingly, with the final-stage differential amplifier 210c, the frequency band is widened while setting the gain thereof to a lower value, thereby ensuring the frequency band necessary for the overall operation of the equalizer 200.

In a case in which the equalizer 200 is configured employing bipolar transistors, the wide frequency band can be obtained by configuring the final-stage employing an emitter follower amplifier, instead of a differential amplifier. However, in a case in which the CMOS process is employed as in the embodiment, an arrangement employing such a source follower amplifier has a problem in that the bias level of the output signal is lowered with respect to the bias level (DC level) of the input signal by the gate-source threshold voltage Vt of the MOSFET. With the equalizer 200 according to the embodiment, a differential amplifier is employed in the final stage, instead of a source follower amplifier, thereby solving this problem.

The parasitic capacitance which occurs on the output side of each of the first-stage differential amplifier 210a and the intermediate-stage differential amplifier 210b is smaller than the parasitic capacitance that occurs at the final-stage differential amplifier 210c. Accordingly, with the first-stage and intermediate-stage differential amplifiers 210a and 20b, the peak value of the gain can be raised without a need to narrow the frequency band. Accordingly, the peak values of the gains g1 and g2 of the first-stage and intermediate-stage differential amplifiers 210a and 210b are set to higher values than that set for the final-stage differential amplifier 210c. Preferably, the gain g1 of the first stage is designed to be a highest value, and the gain g2 of the intermediate stage is designed to a second-highest value.

By designing the frequency properties with respect to the gains of the differential amplifiers 210a through 210c as described above, desired frequency properties gtotal can be obtained for the equalizer 200 as a whole.

Description has been made above regarding the present invention with reference to the embodiments. The above-described embodiment has been described for exemplary purposes only, and is by no means intended to be interpreted restrictively. Rather, it can be readily conceived by those skilled in this art that various modifications may be made by making various combinations of the aforementioned components or processes, which are also encompassed in the technical scope of the present invention. Description will be made below regarding such a modification.

With the equalizer 200 according to the present invention, the number of the stages of the differential amplifiers is not restricted in particular. However, such an arrangement including three stages of differential amplifiers as in the equalizer 200 according to the embodiment provides the following advantage. That is to say, the more the number of the stages of the differential amplifiers 210 is, the greater the degree-of-freedom of adjustment of gain is, but the delay time of the equalizer is also increased. With the above-described arrangement, three stages of the differential amplifiers 210 are provided, thereby allowing the gain frequency properties to be optimized while maintaining the delay time in a suitable range.

The configuration of the differential amplifier 210 is not restricted to such a configuration shown in FIG. 6B. Rather, differential amplifiers having any other configuration may be employed. Furthermore, the gains g1 through g3 set for the stages are not restricted to those shown in FIG. 7. Also, the gains g1 through g3 of these stages may be adjusted in a range without departing from the above-described design method, as long as the desired gain gtotal is obtained for the equalizer 200 as a whole.

The equalizer 200 shown in FIGS. 6A and 6B according to the embodiment can suitably be employed in the HDMI selector shown in FIG. 5. It should be noted that the usage of the equalizer 200 according to the embodiment is not restricted to such an arrangement. Also, the equalizer 200 according to the embodiment may be provided between desired circuits or apparatuses which perform data transmission via differential signal lines.

While the preferred embodiments of the present invention have been described using specific terms, such description is for illustrative purposes only, and it is to be understood that changes and variations may be made without departing from the spirit or scope of the appended claims.

What is claimed is:

1. A differential transmitter which outputs differential signals via a pair of differential signal lines, including:
an input differential pair which includes first and second transistors with one terminals connected to each other so as to form a common terminal, and operates with termination resistors on a receiver side as a load;
a tail current source which supplies constant current to the input differential pair;
an impedance adjusting unit which is provided between the input differential pair and the differential signal lines, and adjusts the load impedance of the first and second transistors.

2. A differential transmitter according to claim 1, wherein the impedance adjusting unit includes a variable impedance element provided between the other terminal of the first transistor and the other terminal of the second transistor.

3. A differential transmitter according to claim 1, wherein the impedance adjusting unit includes a first switch provided between the other terminal of the first transistor and the other terminal of the second transistor.

4. A differential transmitter according to claim 3, wherein the impedance adjusting unit further includes a first resistor provided in series with the first switch between the other terminal of the first transistor and the other terminal of the second transistor.

5. A differential transmitter according to claim 4, wherein the impedance adjusting unit further includes a second resistor provided opposite to the first resistor across the first switch between the other terminal of the first transistor and the other terminal of the second transistor.

6. A differential transmitter according to claim 1, wherein the impedance adjusting unit includes:
a first variable impedance element provided between the other terminal of the first transistor and a power supply terminal; and
a second variable impedance element provided between the other terminal of the second transistor and the power supply terminal.

7. A differential transmitter according to claim 1, wherein the impedance adjusting unit includes:
a second switch provided between the other terminal of the first transistor and a power supply terminal; and
a third switch provided between the other terminal of the second transistor and the power supply terminal.

8. A differential transmitter according to claim 7, wherein the impedance adjusting unit further includes:
a fourth resistor provided in series with the second switch between the other terminal of the first transistor and the power supply terminal; and
a fifth resistor provided in series with the third switch between the other terminal of the second transistor and the power supply terminal.

9. An equalizer which performs waveform-shaping of input differential signals, including a plurality of differential amplifiers connected in a multi-stage manner,
wherein each differential amplifier has a configuration including an input differential pair configured of two MOSFETs (Metal Oxide Semiconductor Field Effect Transistor),
and wherein the gain frequency properties of the stages are set independently of one another.

10. An equalizer according to claim 9, wherein the gain of the final-stage differential amplifier is set to a lowest value.

11. An equalizer according to claim 9, wherein the differential amplifier includes:
an input differential pair configured of two MOSFETs (Metal Oxide Semiconductor Field Effect Transistor);
resistive loads connected to the drain sides of the two MOSFETs;
a tail current source connected to the source sides of the two MOSFETs; and
an impedance circuit provided between the sources of the two MOSFETs,
and wherein the drain-side voltages of the two MOSFETs are output to the next stage.

12. An equalizer according to claim 11, wherein the impedance circuit includes a first resistor and a first capacitor provided in parallel between the sources of the two MOSFETs,
and wherein there is a difference in the resistance of the first resistor and the capacitance of the first capacitor among the stages of the differential amplifiers.

13. An equalizer according to claim 9, wherein the number of the stages of the differential amplifiers is three.

14. An HDMI selector circuit including:
a plurality of the equalizers according to claim 9, each of which receives differential signals stipulated by the HDMI (High-Definition Multimedia Interface) standard, and performs waveform-shaping of the differential signals thus received;
a multiplexer which selects one from among the output signals of the plurality of equalizers; and
a differential transmitter according to claim 1, which outputs the output signals of the multiplexer as differential signals stipulated by the HDMI standard.
